(19) United States
(12) Patent Application Publication
(10) Pub. No.: US 2015/0241492 A1
(43) Pub. Date: Aug. 27, 2015

(54) ANALYZING METHOD OF JUNCTION OF COAXIAL PROBE FOR MEASURING PERMITTIVITY AND ANALYZING APPARATUS THEREOF

(71) Applicant: Electronics and Telecommunications Research Institute, Daejeon (KR)

(72) Inventors: Young Seung LEE, Daejeon (KR); Seung Keun PARK, Daejeon (KR); Hyung Do CHOI, Daejeon (KR)

(73) Assignee: Electronics and Telecommunications Research Institute, Daejeon (KR)

(21) Appl. No.: 14/293,007

(22) Filed: Jun. 2, 2014

(30) Foreign Application Priority Data
Feb. 25, 2014 (KR) 10-2014-0021724

(51) Int. Cl. G01R 27/26; G01R 1/067

(52) U.S. Cl. CPC G01R 27/26; G01R 1/067

(57) ABSTRACT

Disclosed is an analyzing apparatus of a junction of a coaxial probe for measuring permittivity, including: a first calculation module which calculates a first expression for a field of a first area by using an Eigenfunction expansion method; a second calculation module which calculates a second expression for a field of a second area contacting the first area by using an associated Weber transform integral method; a simultaneous equation calculation module which calculates simultaneous equations by using the first expression and the second expression; and an admittance calculation module which calculates admittance for a junction area including the first area and the second area by using the simultaneous equations.

### CROSS-REFERENCE TO RELATED APPLICATIONS

This application claims priority to and the benefit of Korean Patent Application No. 10-2014-0021724 filed in the Korean Intellectual Property Office on Feb. 25, 2014, the entire contents of which are incorporated herein by reference.

### TECHNICAL FIELD

The present invention relates to an analyzing method of a junction of a coaxial probe for measuring permittivity and an analyzing apparatus thereof.

### BACKGROUND ART

Permittivity ∈ is defined as a constant representing a degree in which a dielectric reacts to an externally applied electric field and used as an index thereof that indicates a frequency of an applied electromagnetic wave and whether an interior of a medium is lost. The permittivity is important in terms of ensuring performance in designing a circuit including an antenna and a laminate substrate and is a key parameter to determine shielding efficiency of a shielding cable even in terms of electromagnetic wave suitability. Moreover, the permittivity may be used to determine a moisture content and instability of a material such as a wall surface in determining a characteristic of the electromagnetic wave of a large-sized structure.

A research into a probe for more accurately measuring the permittivity is in progress due to such importance and such demand. Among them, a coaxial probe is advantageous in that an operation is possible in a wide band and the size of a sample to be measured is not limited. The coaxial probe measures the permittivity by measuring equivalent impedance or admittance depending on a mismatch which occurs between a feed coaxial wire and the sample to be measured. However, in the case of an analysis method for the coaxial probe for general permittivity measurement, a reactive component which is caused by a higher mode generated at a mismatch part cannot be more rigorously considered, thereby causing an error in final admittance and permittivity values.

### SUMMARY OF THE INVENTION

The present invention has been made in an effort to provide an analyzing method of a junction of a coaxial probe for measuring permittivity and an analyzing apparatus thereof that can precisely analyze a junction of the coaxial probe.

Technical objects of the present invention are not limited to the aforementioned technical objects and other technical objects which are not mentioned will be apparently appreciated by those skilled in the art from the following description.

An exemplary embodiment of the present invention provides an analyzing apparatus of a junction of a coaxial probe for measuring permittivity, the apparatus comprising: a first calculation module which calculates a first expression for a field of a first area by using an Eigenfunction expansion method; a second calculation module which calculates a second expression for a field of a second area contacting the first area by using an associated Weber transform integral method; a simultaneous equation calculation module which calculates simultaneous equations by using the first expression and the second expression; and an admittance calculation module which calculates admittance for a junction area including the first area and the second area by using the simultaneous equations.

The first area may be defined as a coaxial line area and the second area may be defined as a permittivity measured target area.

The first expression may be defined by Equations 1 and 2 below:

$$\begin{matrix}{H}_{φ}^{i} ( ρ , z ) = \frac{{e}^{i {k}_{1} z}}{ρ} & [ Equation 1 ] \\ {H}_{φ}^{r} ( ρ , z ) = {A}_{0} \frac{{e}^{i {k}_{1} z}}{ρ} + {\sum }_{n = 1}^{∞} {A}_{n} {R}_{1} ( {γ}_{n} ρ ) {e}^{- i {k}_{z} z} & [ Equation 2 ]\end{matrix}$$

where R₁(γₙρ)=J₁(γₙρ)N₀(γₙρ)−N₁(γₙρ)J₀(γₙρ) and b represents the outer radius of the coaxial line of the first area and k₁ represents a wave number of the first area, and k_{z}=\sqrt{k₁²−γₙ²} and γₙ is calculated through R₁(γₙa)=0, a is defined as the radius of the probe of the first area, and H_{φ}ⁱ(ρ,z) represents the incident wave of the magnetic field of the first area and H_{φ}^{r}, (ρ, z) represents the reflection wave of the magnetic field of the first area.

The second expression may be defined by Equation 3 below:

$${H}_{φ}^{t} ( ρ , z ) = {\int }_{0}^{∞} {\tilde{H}}^{t} ( ζ ) {e}^{iκ z} \frac{{Z}_{1} ( ζρ )}{{J}_{0}^{2} ( ζ a ) + {N}_{0}^{2} ( ζ a )} ζ d ζ \qquad [ Equation 3 ]$$

where Z₁(ζρ)=J₁(ζρ)N₀(ζρ)−N₁(ζρ)J₀(ζρ) and a represents the radius of the probe of the first area and k₂ represents a wave number of the second area, and κ=\sqrt{k₂²−ζ₂} and Im κ>0 is defined.

The simultaneous equation calculation module may calculate the simultaneous equations by using a continuity condition of the electric field and the magnetic field on the interface of the first area and the second area.

The continuity condition of the electric field on the interface of the first area and the second area may be defined by Equation 4 below:

$${E}_{ρ}^{i} ( ρ , 0 ) = \{ \begin{matrix}{E}_{ρ}^{i} ( ρ , ) + {E}_{ρ}^{r} ( ρ , 0 ) , & for a < ρ < b \\ 0 , & otherwise\end{matrix} \qquad [ Equation 4 ]$$

where a represents the radius of a probe of the first area, b represents the radius of the outer coaxial line of the first area, E_{ρ}ⁱ(ρ,0) represents an incident wave of the electric field between the first area and the second area and E_{ρ}^{r}(ρ,0) represents a reflection wave of the electric field between the first area and the second area.

The continuity condition of the magnetic field on the interface of the first area and the second area may be defined by Equation 7 below:

H_{φ}^{t}(ρ,0)=H_{φ}ⁱ(ρ,0)H_{φ}^{r}(ρ,0), for a<ρ<b [Equation 7]

where a represents the radius of the probe of the first area, b represents the outer radius of the coaxial line of the first area, H_{φ}ⁱ(ρ,0) represents the incident wave of the magnetic field on the interface between the first area and the second area, and H_{φ}^{r}(ρ,0) represents the reflection wave of the magnetic field on the interface between the first area and the second area.

Another exemplary embodiment of the present invention provides an analyzing method of a junction of a coaxial probe for measuring permittivity, the method comprising: calculating a first expression for a field of a first area by using an Eigenfunction expansion method; calculating a second expression for a field of a second area contacting the first area by using an associated Weber transform integral method; calculating simultaneous equations by using the first expression and the second expression; and calculating admittance for a junction area including the first area and the second area by using the simultaneous equations.

The first area may be defined as a coaxial line area and the second area may be defined as a permittivity measured target area.

In the calculating of the simultaneous equations by using the first expression and the second expression, the simultaneous equations may be calculated by using the continuity condition of the electric field and the magnetic field on the interface of the first area and the second area.

According to exemplary embodiments of the present invention, in an analyzing method of a junction of a coaxial probe for measuring permittivity and an analyzing apparatus thereof, since a characteristic of a junction of a coaxial probe for measuring permittivity is efficiently and rapidly determined based on mathematical development, the junction of the coaxial probe can be precisely analyzed through a shortened calculation process.

Since a change in admittance between a target to be measured and the probe which occurs by the junction can be precisely determined, the analyzing method of a junction of a coaxial probe for measuring permittivity and the analyzing apparatus thereof according to the exemplary embodiment of the present invention can be applied to precise design of the junction and propagation attenuation prediction through determination of an electrical permittivity characteristic of a main material of a large-sized structure.

### BRIEF DESCRIPTION OF THE DRAWINGS

FIG. 1 is a cross-sectional view illustrating a junction of a coaxial probe for measuring permittivity.

FIG. 2 is a block diagram illustrating an analyzing apparatus of a junction of a coaxial probe for measuring permittivity according to an exemplary embodiment of the present invention.

FIG. 3 is a flowchart illustrating an analyzing method of a junction of a coaxial probe for measuring permittivity according to an exemplary embodiment of the present invention.

FIG. 4 is a graph illustrating a convergence degree of an electromagnetic field of on an interface of a first area and a second area used in an admittance calculation process of the analyzing method of a junction of a coaxial probe for measuring permittivity according to the exemplary embodiment of the present invention.

FIGS. 5 and 6 are graphs illustrating a change of an admittance value depending on a change of complex permittivity of a target to be measured.

FIG. 7 is a block diagram illustrating a computing system that executes an analyzing method of a junction of a coaxial probe for measuring permittivity according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Herein, some exemplary embodiments will be described in detail with reference to the exemplary drawings. When reference numerals refer to components of each drawing, it is to be noted that although the same components are illustrated in different drawings, the same components are referred to by the same reference numerals as possible. In describing the embodiments of the present invention, when it is determined that the detailed description of the known configuration or function related to the present invention may interrupt understanding the exemplary embodiments of the present invention, the detailed description thereof will be omitted.

In describing constituent elements of the exemplary embodiment of the present invention, terms such as first, second, A, B, (a), and (b) may be used. The terms are only used to distinguish a constituent element from another constituent element, but nature or an order of the constituent element is not limited by the terms. Unless otherwise defined, all terms used herein including technological or scientific terms have the same meaning as those generally understood by a person with ordinary skill in the art to which the present invention pertains. Terms which are defined in a generally used dictionary should be interpreted to have the same meaning as the meaning in the context of the related art, and are not interpreted as an ideally or excessively formal meaning unless clearly defined in the present invention.

The present invention relates to an analyzing method of a junction of a coaxial probe for measuring permittivity and an analyzing apparatus thereof. In the specification, a ‘junction area’ includes a coaxial line (that is, a first area) of a coaxial probe for measuring permittivity and a measured target (that is, a second area) and indicates an entire area where the coaxial line (that is, the first area) of the coaxial probe and the measured target (that is, the second area) contact and an ‘interface’ may indicate a surface where the coaxial line (that is, the first area) of the coaxial probe and the measured target (that is, the second area) meet.

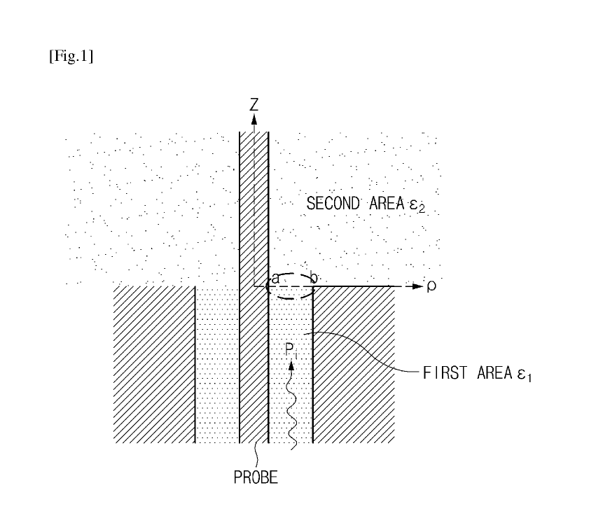

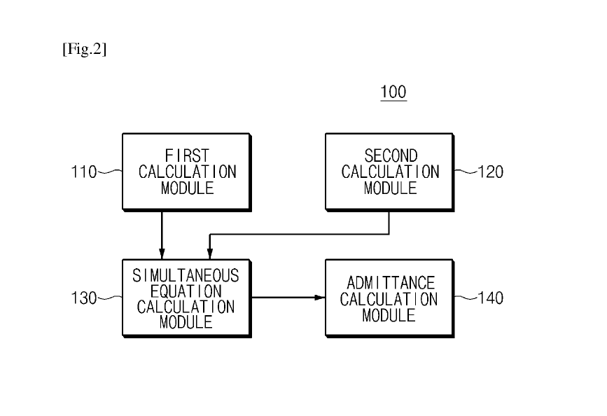

FIG. 1 is a cross-sectional view illustrating a junction of a coaxial probe for measuring permittivity. FIG. 2 is a block diagram illustrating an analyzing apparatus of a junction of a coaxial probe for measuring permittivity according to an exemplary embodiment of the present invention.

First, referring to FIG. 1, the coaxial probe may contact the measured target in order to measure the permittivity. The first area is assumed as a coaxial line area and the second area is assumed as a target (hereinafter, referred to as a ‘measured target’) area of which permittivity is measured. In addition, in FIG. 1, a represents a radius of the probe, b represents a radius of the coaxial line, ∈₁ represents permittivity of the first area, and ∈₂ represents permittivity of the second area. ∈₂ may have complex values when a loss exists.

Referring to FIG. 2, the analyzing apparatus 100 of a junction of a coaxial probe for measuring permittivity according to the exemplary embodiment of the present invention may include a first calculation module 110, a second calculation module 120, a simultaneous equation calculation module 130, and an admittance calculation module 140.

The first calculation module 110 may calculate a first expression for a field of the first area by using an Eigenfunction expansion. The first expression may be expressed as illustrated in Equation 1 and Equation 2 described below. For example, it may be understood that Equation 1 defines an incident wave of a magnetic field of the first area and Equation 2 defines a reflection wave of the magnetic field of the first area.

$$\begin{matrix}{H}_{φ}^{i} ( ρ , z ) = \frac{{e}^{i {k}_{1} z}}{ρ} & [ Equation 1 ] \\ {H}_{φ}^{r} ( ρ , z ) = {A}_{0} \frac{{e}^{i {k}_{1} z}}{ρ} + {\sum }_{n = 1}^{∞} {A}_{n} {R}_{1} ( {γ}_{n} ρ ) {e}^{- i {k}_{z} z} & [ Equation 2 ]\end{matrix}$$

In Equation 1 and Equation 2, R₁(γₙρ)=J₁(γₙρ)N₀(γₙρ)−N₁(γₙρ)J₀(γₙρ) and k₁ represents a wave number of the first area and b represents the radius of the coaxial line. Further, k_{z}=\sqrt{k₁²−γₙ²}, and γₙ may be acquired through R₁(βₙa)=0 and a represents the radius of the probe. H_{φ}ⁱ (ρ,z) represents the incident wave of the magnetic field of the first area and H_{φ}^{r}(ρ,z) represents the reflection wave of the magnetic field of the first area.

The second calculation module 120 may calculate a second expression for a field of the second area by using the associated Weber transform. The associated Weber transform may indicate an integral transform pair given in a form illustrated below.

$$\begin{matrix}\tilde{f} ( ζ ) = {\int }_{a}^{∞} f ( ρ ) {Z}_{μ , V} ( ζρ ) ρ d ρ & ( 1 ) \\ f ( ρ ) = {\int }_{0}^{∞} \tilde{f} ( ζ ) \frac{{Z}_{μ , V} ( ζρ )}{{J}_{v}^{2} ( ζ a ) + {N}_{v}^{2} ( ζ a )} ζ d ζ & ( 2 )\end{matrix}$$

Herein, Equation (1) means forward transform of a coordinate system ρ→ζ and Equation (2) means inverse transform of ζ→ρ, and represents the kernel defined as Z_{μ,v}(ζρ)=J_{μ}(ζρ)Nᵥ(ζa)−N_{μ}(ζρ)Jᵥ(ζa). J_{μ}(•) means a μ-th first type Bessel function and Nᵥ(•) means a v-th second type Bessel function. The forward or inverse transform pair do not exist with respect to all orders of Bessel functions and a case in which orders of the first type and second type Bessel functions are different from each other is particularly called associated Weber integral transform.

The second expression may be expressed as illustrated in Equation 3 below.

$${H}_{φ}^{t} ( ρ , z ) = {\int }_{0}^{∞} {\tilde{H}}^{t} ( ζ ) {e}^{iκ z} \frac{{Z}_{1} ( ζρ )}{{J}_{0}^{2} ( ζ a ) + {N}_{0}^{2} ( ζ a )} ζ d ζ \qquad [ Equation 3 ]$$

Herein, Z₁(ζρ)=J₁(ζρ)N₀(ρa)−N₁(ζρ)J₀(ζa), and k₂ represents a wave number of the second area and a represents the radius of the probe. Further, κ=\sqrt{k₂²−ζ²} and Im κ>0 is defined. Since Z₁(ζρ) includes a variable considering the radius (a) of the probe, the associated Weber transform is performed by considering the radius (a) of the probe in Equation 3.

The simultaneous equation calculation module 130 may calculate simultaneous equations by using the first expression (that is, Equations 1 and 2) calculated from the first calculation module 110 and the second expression (that is, Equation 3) calculated from the second calculation module 120.

In detail, the simultaneous equation calculation module 130 may calculate simultaneous equations for discrete mode coefficients (A₀ and Aₙ) by using continuity conditions of tangent components of the electric field and a magnetic field on the interface of the first area and the second area.

First, the continuity condition of the electric field between the first area and the second area may be expressed as illustrated in Equation 4 below.

$${E}_{ρ}^{i} ( ρ , 0 ) = \{ \begin{matrix}{E}_{ρ}^{i} ( ρ , 0 ) + {E}_{ρ}^{r} ( ρ , 0 ) , & for a < ρ < b \\ 0 , & otherwise\end{matrix} \qquad [ Equation 4 ]$$

Herein, a represents the radius of the probe and b represents the radius of the coaxial line. Further, E_{ρ}ⁱ(ρ,0) represents an incident wave of the electric field of the interface between the first area and the second area and E_{ρ}^{r}(ρ, 0) represents a reflection wave of the electric field of the interface between the first area and the second area.

The simultaneous equation calculation module 130 uses a relationship of

$${E}_{ρ} = \frac{1}{iωɛ} \frac{\partial {H}_{Φ}}{\partial z}$$

with Equation 4 and may calculate Equation 5 as described below by substituting Equations 1, 2, and 3 in Equation 4.

$$\frac{1}{{ωɛ}_{2}} {\int }_{0}^{∞} {\tilde{H}}^{t} ( ζ ) κ \frac{{Z}_{1} ( ζρ )}{{J}_{0}^{2} ( ζ a ) + {N}_{0}^{2} ( ζ a )} ζ d ζ = \{ \begin{matrix}{η}_{1} \frac{1 - {A}_{0}}{ρ} - \frac{1}{{ωɛ}_{1}} {\sum }_{n = 1}^{∞} {A}_{n} {k}_{z} {R}_{1} ( {γ}_{n} ρ ) , & for a < ρ < b \\ 0 , & otherwise\end{matrix} \qquad [ Equation 5 ]$$

Herein, a represents the radius of the probe, b represents the radius of the coaxial line, and A₀ and Aₙ represent the discrete coefficients. η₁ represents the intrinsic impedance of the first area and defined as

$${η}_{1} = \frac{{k}_{1}}{{ωɛ}_{1}} .$$

The simultaneous equation calculation module 130 performs the associated Weber transform of both sides of Equation 5 (that is, multiplies both sides by Z₁(ζρ), which is integrated as ∫ₐ^{∞}ηdη) to calculate Equation 6 below.

$${\tilde{H}}^{t} ( ζ ) = \frac{1}{κ} [ ( 1 - {A}_{0} ) {k}_{1} ɛ {I}_{0} - ɛ {I}_{0} - ɛ {\sum }_{n = 1}^{∞} {A}_{n} {k}_{z} {I}_{n} ] \qquad [ Equation 6 ]$$

Herein, A₀ and Aₙ represent the discrete coefficients and

$$ɛ = \frac{{ɛ}_{2}}{{ɛ}_{1}} , \\ {I}_{0} = {\int }_{a}^{b} {Z}_{1} ( ζρ ) d ρ = - \frac{1}{ζ} {Z}_{0} ( ζ b ) , \\ and$$

$${I}_{n} = - 2 ζ \frac{{Z}_{0} ( ζ b )}{{πγ}_{n} ( {ζ}^{2} - {γ}_{n}^{2} )}$$

may be defined.

The continuous condition of the magnetic field between the first area and the second area may be expressed as illustrated in Equation 7 below.

H_{φ}^{t}(ρ,0)=H_{φ}ⁱ(ρ,0)+H_{φ}^{r}(ρ,0), for a<ρ<b [Equation 7]

Herein, a represents the radius of the probe, b represents the radius of the coaxial line, and H_{φ}ⁱ(ρ,0) represents the incident wave of the magnetic field of the interface between the first area and the second area and H_{φ}^{r}(ρ,0) represents the reflection wave of the magnetic field of the interface between the first area and the second area.

The simultaneous equation calculation module 130 may calculate Equation 8 as described below by substituting Equations 1, 2, and 3 in Equation 7.

$${\int }_{0}^{∞} {\tilde{H}}^{t} ( ζ ) \frac{{Z}_{1} ( ζρ )}{{J}_{0}^{2} ( ζ a ) + {N}_{0}^{2} ( ζ a )} ζ d ζ = \frac{1 + {A}_{0}}{ρ} + {\sum }_{n = 1}^{∞} {A}_{n} {R}_{1} ( {γ}_{n} ρ ) \qquad [ Equation 8 ]$$

Herein, a represents the radius of the probe, and A₀ and Aₙ represent the discrete coefficients.

The simultaneous equation calculation module 130 may calculate a first equation such as Equation 9 below by substituting

$$( ζ )$$

of Equation 6 in Equation 8, multiplying both sides of Equation 8 by ρR₁(γₚρ), and integrating dρ at an interval of a<ρ<b.

$$( 1 - {A}_{0} ) {I}_{0 p} - {\sum }_{n = 1}^{∞} {A}_{n} {I}_{np} = \frac{1}{ɛ} {A}_{p} \frac{2}{{π}^{2} {γ}_{p}^{2}} [ 1 - \frac{{J}_{0}^{2} ( {γ}_{p} b )}{{J}_{0}^{2} ( {γ}_{p} a )} ] \qquad [ Equation 9 ]$$

Herein, a represents the radius of the probe, b represents the radius of the coaxial line, and A₀ and Aₙ represent the discrete coefficients. Further,

$${I}_{0 p} = {k}_{1} {\int }_{0}^{∞} \frac{1}{κ} \frac{{I}_{0} {I}_{p}}{{J}_{0}^{2} ( ζ a ) + {N}_{0}^{2} ( ζ a )} ζ d ζ$$

$$and$$

$${I}_{np} = {k}_{z} {\int }_{0}^{∞} \frac{1}{κ} \frac{{I}_{n} {I}_{p}}{{J}_{0}^{2} ( ζ a ) + {N}_{0}^{2} ( ζ a )} ζ d ζ$$

may be defined.

The simultaneous equation calculation module 130 may calculate a second equation such as Equation 10 below by substituting

$$( ζ )$$

of Equation 6 in Equation 8 and integrating dρ at the interval of a<ρ<b.

$$( 1 - {A}_{0} ) {I}_{00} - {\sum }_{n = 1}^{∞} {A}_{n} {I}_{n 0} = \frac{1}{ɛ} ( 1 + {A}_{0} ) ln b / a \qquad [ Equation 10 ]$$

Herein, a represents the radius of the probe, b represents the radius of the coaxial line, and A₀ and Aₙ represent the discrete coefficients.

$${I}_{00} = {k}_{1} {\int }_{0}^{∞} \frac{1}{κ} \frac{{I}_{0} {I}_{0}}{{J}_{0}^{2} ( ζ a ) + {N}_{0}^{2} ( ζ a )} ζ d ζ$$

$$and$$

$${I}_{n 0} = {k}_{z} {\int }_{0}^{∞} \frac{1}{κ} \frac{{I}_{n} {I}_{0}}{{J}_{0}^{2} ( ζ a ) + {N}_{0}^{2} ( ζ a )} ζ d ζ$$

may be defined.

The calculated first equation (that is, Equation 9) and second equation (that is, Equation 10) may constitute the simultaneous equations.

The admittance calculation module 140 may acquire the electric field and the magnetic field by using the discrete mode coefficients A₀ and Aₙ acquired by calculating solutions of the simultaneous equations calculated by the simultaneous equation calculation module 130, and calculate admittance represented by Equation 11 below by using a ratio of the electric field and the magnetic field on the interface.

$$Y = \frac{2 π}{ln ( b / a )} \frac{{\int }_{d}^{b} {E}_{p} ( ρ , 0 ) d ρ}{{\int }_{a}^{b} {E}_{ρ} ( ρ , 0 ) d ρ} \qquad [ Equation 11 ]$$

Herein, a represents the radius of the probe and b represents the radius of the coaxial line.

As described above, in the analyzing apparatus 100 of a junction of a coaxial probe for measuring permittivity according to the exemplary embodiment of the present invention, since a characteristic of a junction of a coaxial probe for measuring permittivity is efficiently and rapidly determined (e.g., admittance is calculated) based on mathematical development, the junction of the coaxial probe can be precisely analyzed through a shortened calculation process. In detail, the first expression (that is, Equations 1 and 2) and the second expression (that is, Equation 3) based on the associated Weber transform and the Eigenfunction expansion have a characteristic to minutely express the electromagnetic wave by considering an interfacing condition of the first area and the second area and an advantage that the solutions of the simultaneous equations are rapidly converged due to a characteristic of a grade.

The existing coaxial measurement probe technology has a problem that a reflection effect caused by an exterior wall of a sample having a finite size occurs in a part where a measured target is located, while the analyzing apparatus 100 of a junction of a coaxial probe for measuring permittivity according to the exemplary embodiment of the present invention has an advantage even in a structural aspect that the junction of the coaxial probe is not affected by the exterior wall of the sample.

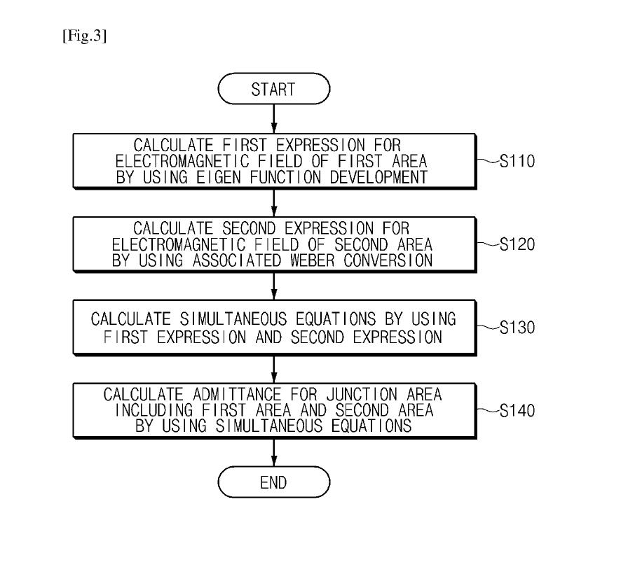

FIG. 3 is a flowchart illustrating an analyzing method of a junction of a coaxial probe for measuring permittivity according to an exemplary embodiment of the present invention.

Referring to FIG. 3, the analyzing method of a junction of a coaxial probe for measuring permittivity according to the exemplary embodiment of the present invention may include calculating a first expression for an electromagnetic field of a first area by using Eigenfunction expansion (S110), calculating a second expression for the electromagnetic field of a second area by using associated Weber transform (S120), calculating simultaneous equations by using the first expression and the second expression (S130), and calculating admittance for a junction area including the first area and the second area by using the calculated simultaneous equations (S140).

Hereinafter, steps S110 to S140 will be described in detail with reference to FIGS. 1 and 2.

First, in step S110, a first calculation module 110 may calculate the first expression for the electromagnetic field of the first area by using the Eigen function expansion. The first expression may be expressed as illustrated in Equations 1 and 2 above.

In step S120, a second calculation module 120 may calculate the second expression for the electromagnetic field of the second area by using associated Weber transform. The second expression may be expressed as illustrated in Equation 3 above.

In step S130, the simultaneous equation calculation module 130 may calculate simultaneous equations by using the first expression (that is, Equations 1 and 2) calculated from the first calculation module 110 and the second expression (that is, Equation 3) calculated from the second calculation module 120. That is, the simultaneous equation calculation module 130 may calculate simultaneous equations for discrete mode coefficients A₀ and Aₙ by using a continuity condition of tangent components of an electric field and a magnetic field on an interface of the first area and the second area. Since a simultaneous equation calculation process is the same as the process described with reference to Equations 4 to 10, a detailed description thereof will be skipped. The calculated first equation (that is, Equation 9) and second equation (that is, Equation 10) may constitute the simultaneous equations.

In step S140, an admittance calculation module 140 may acquire the electric field and the magnetic field by using the discrete mode coefficients A₀ and Aₙ acquired by calculating solutions of the simultaneous equations calculated by the simultaneous equation calculation module 130, and calculate admittance represented by Equation 11 below by using a ratio of the electric field and the magnetic field on the interface.

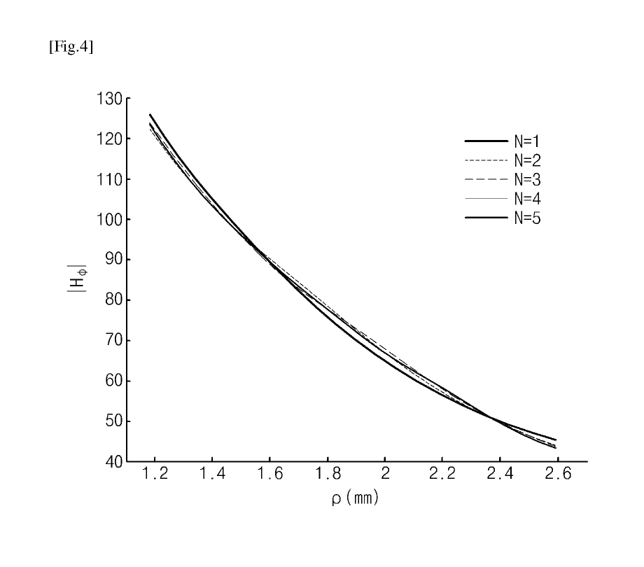

FIG. 4 is a graph illustrating a convergence degree of an electromagnetic field of an interface of a first area and a second area used in an admittance calculation process of the analyzing method of a junction of a coaxial probe for measuring permittivity according to the exemplary embodiment of the present invention.

In detail, FIG. 4 illustrates a convergence degree of the electromagnetic field on the interface when it is assumed that a feed frequency (f) is 2.45 GHz, a radius (a) of the probe is 1.18 mm, a radius (b) of a coaxial line is 2.655 mm, permittivity (∈ₗ) of the first area is 1, and permittivity (∈₂) of the second area is 2. Referring to FIG. 4, it can be seen that the electromagnetic field of the interface is converged to a value which substantially coincides with the previous value only by a high mode term having approximately four unknown discrete coefficients.

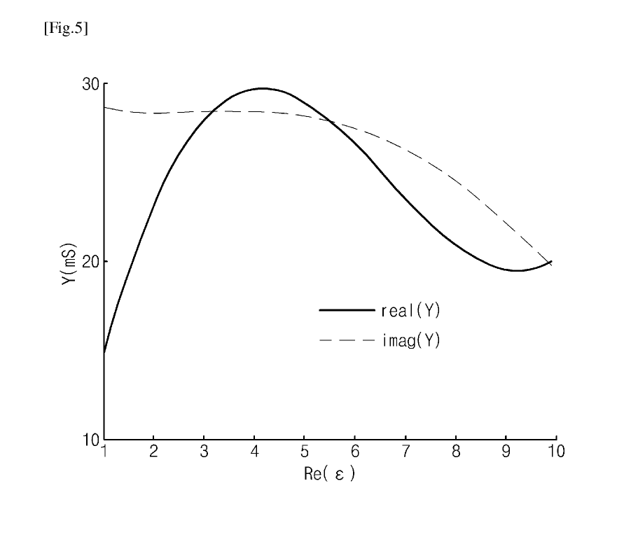

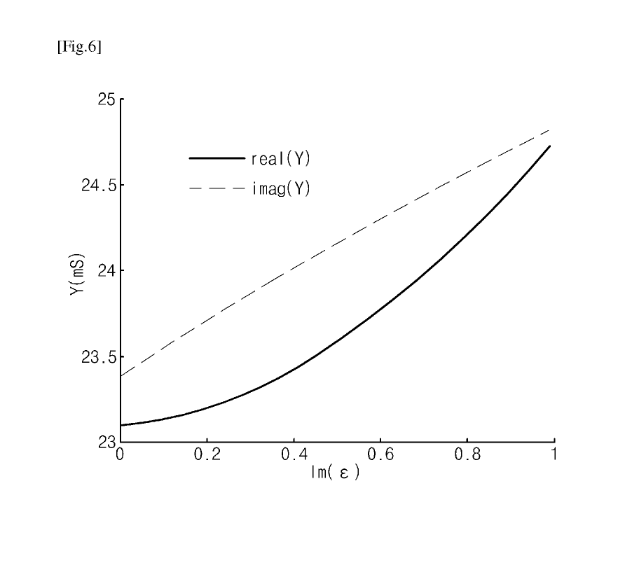

FIGS. 5 and 6 are graphs illustrating a change of an admittance value depending on a change of complex permittivity of a measured target.

In detail, FIG. 5 illustrates a real number part and an imaginary number part of admittance which vary as a real number part Re(∈₂) of permittivity of the measured target is changed and FIG. 6 illustrates a real number part and an imaginary number part of admittance which vary as an imaginary number part Im(∈₂) of the permittivity of the measured target is changed.

Referring to FIGS. 5 and 6, it can be seen that the admittance of the probe junction which sensitively varies depending on permittivity by the unit of mS, is efficiently predicted and in particular, such a characteristic is remarkably shown in the change of the imaginary number part of the permittivity depending on an electrical loss of the measured target. Therefore, an admittance characteristic database depending on the size of the junction and/or the change of the permittivity of the measured target is constructed to be applied to accurate analyzing and designing the junction of the coaxial probe.

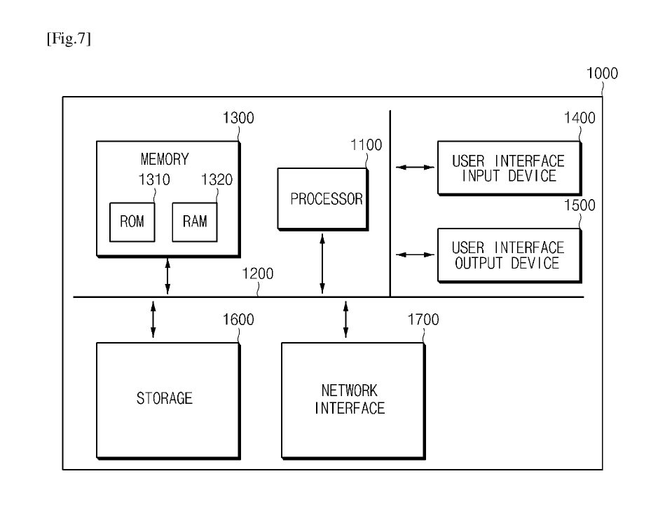

FIG. 7 is a block diagram illustrating a computing system that executes an analyzing method of a junction of a coaxial probe for measuring permittivity according to an exemplary embodiment of the present invention.

Referring to FIG. 7, the computing system 1000 may include at least one processor 1100, a memory 1300, a user interface input device 1400, a user interface output device 1500, a storage 1600, and a network interface 1700 connected through a bus 1200.

The processor 1100 may be a semiconductor device that processes commands stored in a central processing unit (CPU) or the memory 1300 and/or the storage 1600. The memory 1300 and the storage 1600 may include various types of volatile or nonvolatile storage media. For example, the memory 1300 may include a read only memory (ROM) and a random access memory (RAM).

Accordingly, steps of the method or algorithm described in association with the exemplary embodiments disclosed in the specification may be directly implemented by a hardware module, a software module or a combination thereof executed by the processor 100. The software module may reside in storage media (that is, the memory 1300 and/or the storage 1600) such as a RAM, a flash memory, a ROM, an EPROM, an EEPROM, a register, a hard disk, an attachable disk, and a CD-ROM. An exemplary storage medium may be coupled to the processor 1100, and the processor 1100 may read information from the storage medium and write information in the storage medium. As another method, the storage medium may be integrated with the processor 1100. The processor and the storage medium may reside in an application specific integrated circuit (ASIC). The ASIC may reside in a user terminal. As another method, the processor and the storage medium may reside in the user terminal as individual components.

Various exemplary embodiments of the present invention have been just exemplarily described, and various changes and modifications may be made by those skilled in the art to which the present invention pertains without departing from the scope and spirit of the present invention. Accordingly, the exemplary embodiments disclosed herein are intended not to limit the technical spirit of the present invention but to describe the technical spirit, and the scope of the technical spirit of the present invention is limited to the exemplary embodiments. The scope of the present invention may be interpreted by the appended claims and all the technical spirit in the equivalent range thereto should be interpreted to be embraced by the claims of the present invention.

What is claimed is:

1. An analyzing apparatus of a junction of a coaxial probe for measuring permittivity, the apparatus comprising:
a first calculation module which calculates a first expression for a field of a first area by using an Eigenfunction expansion method;
a second calculation module which calculates a second expression for a field of a second area contacting the first area by using an associated Weber transform integral method;
a simultaneous equation calculation module which calculates simultaneous equations by using the first expression and the second expression; and
an admittance calculation module which calculates admittance for a junction area including the first area and the second area by using the simultaneous equations.

2. The apparatus of claim 1, wherein the first area is defined as a coaxial line area and the second area is defined as a permittivity measured target area.

3. The apparatus of claim 2, wherein the first expression is defined by Equations 1 and 2 below:
$$\begin{matrix}{H}_{φ}^{i} ( ρ , z ) = \frac{{e}^{i {k}_{1} z}}{ρ} & [ Equation 1 ] \\ {H}_{φ}^{r} ( ρ , z ) = {A}_{0} \frac{{e}^{i {k}_{1} z}}{ρ} + {\sum }_{n = 1}^{∞} {A}_{n} {R}_{1} ( {γ}_{n} ρ ) {e}^{- i {k}_{z} z} & [ Equation 2 ]\end{matrix}$$
where R₁(γₙρ)=J₁(γₙρ)N₀(γₙρ)−N₁(γₙρ)J₀(γₙρ) and b represents the radius of the coaxial line of the first area and k₁ represents a wave number of the first area, k_{z}=\sqrt{k₁²−γₙ²} and γₙ and is calculated through R₁(γₙa)=0, a is defined as the radius of the probe of the first area, and H_{φ}ⁱ(ρ,z) represents the incident wave of the magnetic field of the first area and H_{φ}^{r}(ρ,z) represents the reflection wave of the magnetic field of the first area.

4. The apparatus of claim 2, wherein the second expression is defined by Equation 3 below:
$${H}_{φ}^{t} ( ρ , z ) = {\int }_{0}^{∞} {\tilde{H}}^{t} ( ζ ) {e}^{i k z} \frac{{Z}_{1} ( ζρ )}{{J}_{0}^{2} ( ζ a ) + {N}_{0}^{2} ( ζ a )} ζ d ζ \qquad [ Equation 3 ]$$
where Z₁(ζρ)=J₁(ζρ)N₀(ζa)−N₁(ζρ)J₀(ζa) and a represents the radius of the probe of the first area and k₂ represents a wave number of the second area, and κ=\sqrt{k₂²−ζ²} and Im κ>0 is defined.

5. The apparatus of claim 2, wherein the simultaneous equation calculation module calculates the simultaneous equations by using a continuous condition of the electric field and the magnetic field on the interface of the first area and the second area.

6. The apparatus of claim 5, wherein the continuous condition of the electric field on the interface of the first area and the second area is defined by Equation 4 below:
$${E}_{ρ}^{t} ( ρ , 0 ) = \{ \begin{matrix}{E}_{ρ}^{i} ( ρ , 0 ) + {E}_{ρ}^{r} ( ρ , 0 ) , & for a < ρ < b \\ 0 , & otherwise\end{matrix} \qquad [ Equation 4 ]$$
where a represents the radius of a probe of the first area, b represents the radius of the coaxial line of the first area, E_{ρ}ⁱ(ρ,0) represents an incident wave of the electric field between the first area and the second area and E_{ρ}^{r}(ρ,0) represents a reflection wave of the electric field between the first area and the second area.

7. The apparatus of claim 5, wherein the continuity condition of the magnetic field on the interface of the first area and the second area is defined by Equation 7 below:
H_{φ}^{t}(ρ,0)=H_{φ}ⁱ(ρ,0)+H_{φ}^{r}(ρ,0), for a<ρ<b [Equation 7]
where a represents the radius of the probe of the first area, b represents the radius of the coaxial line of the first area, H_{φ}ⁱ(ρ,0) represents the incident wave of the magnetic field on the interface between the first area and the second area, and H_{φ}^{r}(ρ,0) represents the reflection wave of the magnetic field on the interface between the first area and the second area.

8. An analyzing method of a junction of a coaxial probe for measuring permittivity, the method comprising:
calculating a first expression for a field of a first area by using an Eigenfunction expansion method;
calculating a second expression for a field of a second area contacting the first area by using an associated Weber transform integral method;
calculating simultaneous equations by using the first expression and the second expression; and
calculating admittance for a junction area including the first area and the second area by using the simultaneous equations.

9. The method of claim 8, wherein the first area is defined as a coaxial line area and the second area is defined as a permittivity measured target area.

10. The method of claim 9, wherein in the calculating of the simultaneous equations by using the first expression and the second expression, the simultaneous equations are calculated by using the continuous condition of the electric field and the magnetic field on the interface of the first area and the second area.
